(19) United States
(12) Patent Application Publication
(10) Pub. No.: US 2008/0217681 A1
(43) Pub. Date: Sep. 11, 2008

(54) Charge trap memory device and method of manufacturing the same

(75) Inventors: Sang-moo Choi, Yongin-si (KR); Kwang-soo Seol, Suwon-si (KR); Sang-jin Park, Yongin-si (KR); Jung-hun Sung, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/979,425

(22) Filed: Nov. 2, 2007

(30) Foreign Application Priority Data
Mar. 9, 2007 (KR) 10-2007-0023675

(51) Int. Cl. H01L 29/792; H01L 21/28

(52) U.S. Cl. 257/324; 438/591; 257/E21.18; 257/E29.309

(57) ABSTRACT

Provided are a charge trap memory device and method of manufacturing the same. A charge trap memory device may include a tunnel insulating layer on a substrate, a charge trap layer on the tunnel insulating layer, and a blocking insulating layer formed of a material including Gd or a smaller lanthanide element on the charge trap layer.

### PRIORITY STATEMENT

This application claims priority under 35 U.S.C. § 119 to Korean Patent Application No. 10-2007-0023675, filed on Mar. 9, 2007, in the Korean Intellectual Property Office (KIPO), the entire contents of which are incorporated herein by reference.

### BACKGROUND

1. Field

Example embodiments relate to a semiconductor memory device and a method of manufacturing the same. Other example embodiments relate to a charge trap memory device having a blocking insulating layer formed of a material that ensures a relatively high dielectric constant and a relatively large energy band gap simultaneously, and a method of manufacturing the same.

2. Description of the Related Art

From among semiconductor memory devices, non-volatile memory devices are storage media that may preserve stored data even when the power is turned off. A configuration of a memory cell, which is a basic element in the non-volatile semiconductor memory device, may vary according to the application fields of the non-volatile memory devices. In the case of NAND type flash memory devices, which are non-volatile semiconductor memory devices having increased capacities, a gate of a transistor may include a floating gate storing charges, e.g., data, and a control gate, which are sequentially stacked.

In the flash memory device, the size of the memory cell may be reduced in order to satisfy the demands for increasing memory capacities. In addition, according to the reduction in the size of the memory cell, a height of the floating gate may be efficiently reduced a vertical direction. In order to reduce the height of the memory cell in the vertical direction, and at the same time, maintain a memory property of the memory cell, for example, a retention property to maintain the data stored for a relatively long time, a semiconductor memory device having a silicon-oxide-nitride-oxide-semiconductor (SONOS), which is formed of a silicon nitride layer (Si₃N₄), not a floating gate, or a metal-oxide-insulator-oxide-semiconductor (MOIOS), e.g., a metal-oxide-nitride-oxide-semiconductor (MONOS), memory device has been suggested.

In addition, research in the area of semiconductor memory devices is being performed. The SONOS may use a silicon material as the control gate, and the MONOS may use a metal material as the control gate. The MOIOS memory device may use a charge trap layer, e.g., the silicon nitride layer (Si₃N₄), as a unit for storing electrical charges, instead of using the floating gate. For example, the MOIOS memory device may be formed by substituting a stacked structure (a floating gate and insulating layers on upper and lower portions of the floating gate) of the memory cell in the flash memory device with a stacked structure (ONO), in which an oxide, a nitride, and an oxide are sequentially stacked. Thus, a threshold voltage of the MOIOS memory device may be shifted because the electrical charges may be trapped by the nitride layer.

A conventional structure of the SONOS memory device is as follows. A first silicon oxide layer (SiO₂) may be formed as a tunnel insulating layer on a semiconductor substrate between source and drain regions, e.g., on a channel region, so that both ends of the first silicon layer may contact the source and drain regions. The first silicon oxide layer may be a layer for tunneling the electrical charges. A silicon nitride layer (Si₃N₄) may be formed on the first silicon oxide layer as the charge trap layer. The silicon nitride layer may be a material layer substantially storing the data, and the electrical charges tunneling the first silicon oxide layer may be trapped in the silicon nitride layer. A second silicon oxide layer may be formed on the silicon nitride layer as a blocking insulating layer that blocks the electrical charges moving upward through the silicon nitride layer. A gate electrode may be formed on the second silicon oxide layer.

However, in the SONOS memory device having the above structure, the dielectric constants of the silicon nitride layer and the silicon oxide layers may be relatively low, density of a trap site in the silicon nitride layer may not be sufficient, and thus, an operating voltage of the memory device may be relatively high. In addition, data recording speed (program speed) and charge retention times in both vertical and horizontal directions may not be sufficient. An aluminum oxide layer (Al₂O₃) having a larger dielectric constant than the silicon oxide layer may be used as the blocking insulating layer instead of the silicon oxide layer, and thus, the program speed and the retention characteristics may improve.

The material of the aluminum oxide layer may have a dielectric constant that is about twice the dielectric constant of the material of the silicon oxide layer, and thus, may advantageously increase the program speed. The dielectric constant of silicon oxide (SiO₂) may be about 3.9, however, the dielectric constant of the aluminum oxide (Al₂O₃) may be about 9. For example, in order to increase the program speed, a relatively large voltage may be applied to the tunnel insulating layer. When the dielectric constant of the material forming the blocking insulating layer is increased, the voltage that is applied may also increase. Because the silicon oxide layer has a relatively small dielectric constant, increasing the program speed may be disadvantageous.

However, if aluminum oxide material is used to form the blocking insulating layer, because the dielectric constant of the aluminum oxide material is about twice of the dielectric constant of the silicon oxide material, the voltage that may be applied to the tunnel insulating layer may increase, and thus, the program speed may increase.

On the other hand, if the dielectric constant of the material that is used to form the blocking insulating layer is relatively large, erase characteristics may be advantageous. For example, when the material having a relatively large dielectric constant is used, a physical thickness of the blocking insulating layer may be increased. Otherwise, the voltage applied to the blocking insulating layer may be reduced while the voltage applied to the tunnel insulating layer is increased when an erase operation is performed. If the relatively thick blocking insulating layer is used or the voltage applied to the blocking insulating layer is relatively low, the number of electrons transmitted from the gate electrode may be reduced, and thus, the erase characteristics may be improved. In addition, when the voltage applied to the tunnel insulating layer is relatively large, the speed of holes transmitted from the substrate may be increased, and thus, the erase characteristics may be improved.

On the other hand, when the dielectric constant of the material is increased, an energy band gap may be reduced, however, the small energy band gap may degrade the erase characteristics. The electrons may be induced into the charge trap layer from the gate electrode by a negative bias voltage applied when the erase operation is performed due to the relatively small energy band gap.

### SUMMARY

Example embodiments provide a charge trap memory device having a blocking insulating layer formed of a material having a relatively high dielectric constant and a relatively large energy band gap in order to increase the program speed and improve the erase characteristics simultaneously, and a method of manufacturing the same.

According to example embodiments, a charge trap memory device may include a tunnel insulating layer on a substrate, a charge trap layer on the tunnel insulating layer, and a blocking insulating layer formed of a material including Gd or a smaller lanthanide element on the charge trap layer.

According to example embodiments, a method of manufacturing a charge trap memory device may include forming a tunnel insulating layer on a substrate, forming a charge trap layer on the tunnel insulating layer, and forming a blocking insulating layer formed of a material including Gd or a smaller lanthanide element on the charge trap layer.

According to example embodiments, the blocking insulating layer may be formed of a material including Gd or smaller lanthanides, and aluminum (Al). The blocking insulating layer may be formed of a material including a combination of Gd or smaller lanthanide (Ln)—Al—O. The blocking insulating layer may be formed of a material including Gd or smaller lanthanide (Ln), aluminum, and nitrogen.

The blocking insulating layer may be formed of GdAlON. The charge trap layer may be formed of a material including silicon. The charge trap layer may include a SiN material. The charge trap layer may be formed of one of the materials selected from polysilicon, nitride material, nanodots, and high-k dielectric materials. The charge trap memory device may further include a gate electrode on the blocking insulating layer.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIG. 1 is a transmission electron microscopy (TEM) analyzing photograph of a sample in which a La—Al—O high dielectric constant insulating layer is formed on a SiN charge trap layer, after subjecting the sample to a thermal process according to example embodiments;

FIGS. 2 and 3 illustrate an X-ray diffraction (XRD) analyzing result and a composition analyzing result of the La—Al—O high dielectric constant insulating layer deposited on the SiN layer of FIG. 1 after the thermal process according to example embodiments;

FIG. 4 illustrates a degree of reaction of lanthanides (Ln) with a lower silicon according to example embodiments;

FIG. 5 schematically illustrates a charge trap memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Hereinafter, a charge trap memory device according to example embodiments will be described in detail with reference to accompanying drawings. Example embodiments may, however, be embodied in many different forms and should not be construed as being limited to the embodiments set forth herein. Rather, these embodiments are provided so that this disclosure will be thorough and complete, and will fully convey the scope of example embodiments to one skilled in the art. In the drawings, the thicknesses of layers and regions are exaggerated for clarity. Like numbers refer to like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to example embodiments, a blocking insulating layer may include a material, e.g., a lanthanide, which may ensure a relatively high dielectric constant and a relatively large band gap at the same time. In addition, an interfacial reaction, which is required to use the insulating layer including the lanthanides (Ln) as the blocking insulating layer in the charge trap memory device, may be adjusted. The lanthanides (Ln) are 14 elements from Ce (58) to Lu (71), or 15 elements including La.

For example, an energy band gap of a LaAlO material may be noticeably large to be similar to that of an aluminum oxide material (Al₂O₃), and at the same time, the LaAlO material may have a dielectric constant larger than that of the aluminum oxide material (Al₂O₃). According to an experiment performed by the inventors, an energy band gap of the aluminum oxide material (Al₂O₃) was about 6.1 eV ˜about 6.2 eV, and a dielectric constant of the aluminum oxide material (Al₂O₃) was about 9. On the other hand, an energy band gap of a LaAlO₃ compound was about 5.65 eV and a dielectric constant of the LaAlO₃ compound was about 12, and an energy band gap of a La₄Al₂O₉ compound was about 5.95 eV and a dielectric constant of the La₄Al₂O₉ compound was about 20.

As described above, the LaAlO₃ compound and the La₄Al₂O₉ compound have a relatively large energy band gap without reducing the dielectric constant. Actually, the LaAlO₃ compound or the La₄Al₂O₉ compound have a relatively large energy band gap that is similar to that of the aluminum oxide material, while having a dielectric constant larger than that of the aluminum oxide material. Therefore, when the blocking insulating layer includes one of the lanthanides (Ln), the blocking insulating layer may realize a relatively high dielectric constant and a relatively large band gap.

However, when a charge trap layer of the charge trap memory device is formed of an SiN layer and the blocking insulating layer is formed of the relatively high dielectric constant insulating layer including La—Al—O compound, the relatively high dielectric constant insulating layer having the La—Al—O compound may react with the SiN, thereby the relatively high dielectric constant insulating layer has a different crystal structure of La₅Si₃NO₁₂. The SiN layer may be a Si₃N₄ layer.

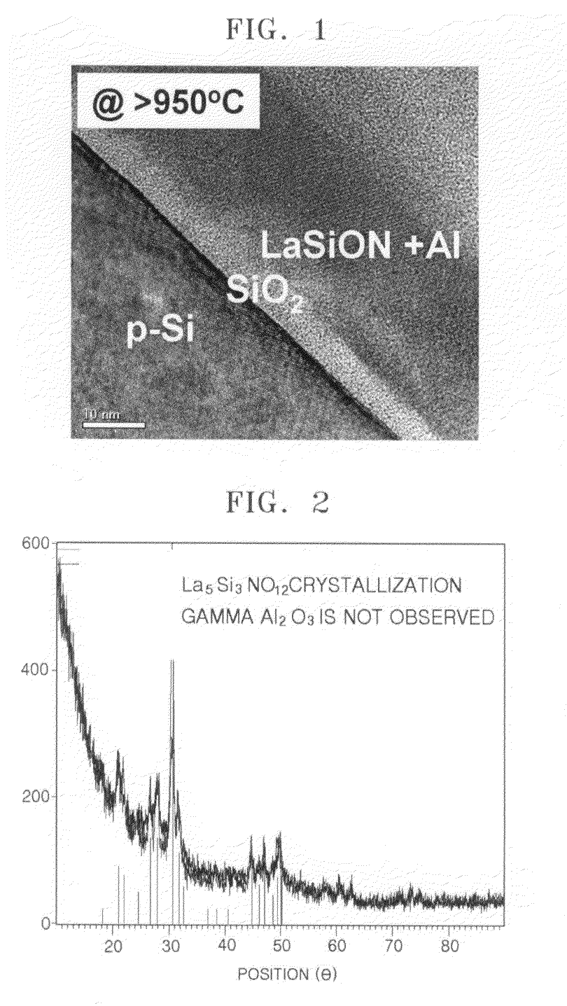

FIG. 1 is a transmission electron microscopy (TEM) analyzing photograph illustrating a sample in which the La—Al—O high dielectric constant insulating layer may be on the SiN charge trap layer, after subjecting the sample to a thermal process. Referring to FIG. 1, the lower layer, for example, the SiN layer, may not be observed after performing the thermal process at a temperature of about 950° C. due to a relatively large reactivity of the La element.

According to the experiment performed by the inventors, a small portion of an SiN layer may remain when the thermal process was performed at a temperature of about 800° C. However, in order to fabricate the charge trap memory device, the thermal process for forming source/drain regions may be performed, for example, for about 20 minutes at a temperature of about 850° C., and thus, the SiN layer may not remain after the reaction with the La element. The thermal process may be performed to fabricate the charge trap memory device. Therefore, thermal stabilities of the charge trap layer and the blocking insulating layer may be required.

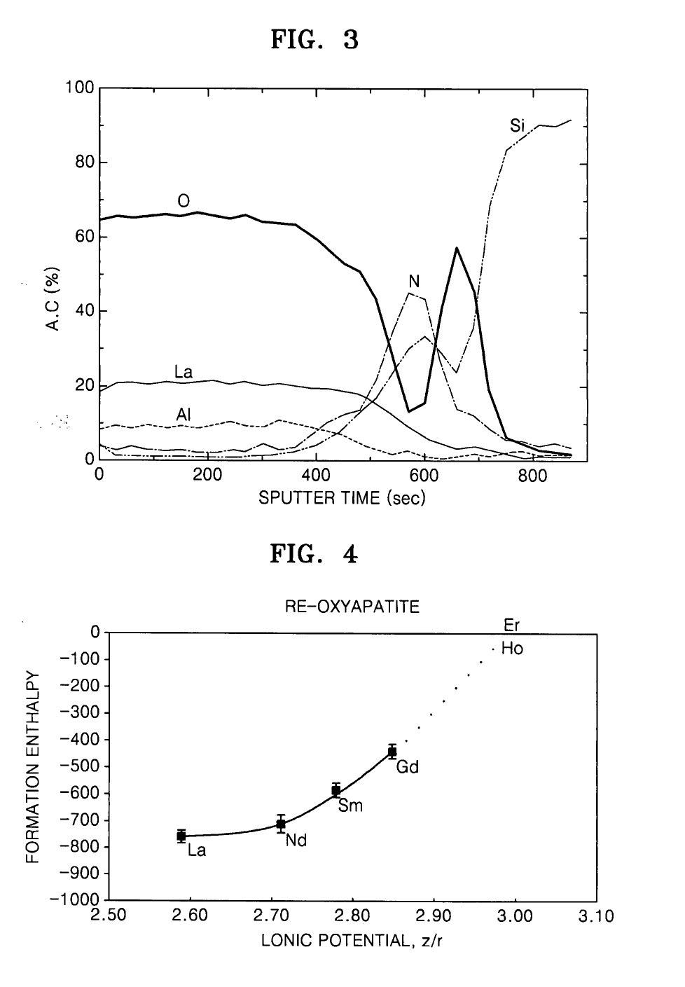

FIGS. 2 and 3 illustrate an X-ray diffraction (XRD) analyzing result and a composition analyzing result of the La—Al—O high dielectric constant insulating layer deposited on the SiN layer after performing the thermal process shown in FIG. 1. In FIG. 3, a horizontal axis denotes a sputtering time, and a vertical axis denotes a content of an element.

As shown in FIGS. 2 and 3, after performing the thermal process, the La—Al—O high dielectric constant insulating layer may react with the SiN. Therefore, an entirely different crystallized structure of La₅Si₃NO₁₂ was exhibited. In addition, as shown in FIG. 3, aluminum (Al) may not be included in the crystallized structure. For example, although the Al element exists, the Al element may not contribute to crystallization and may remain as a metal.

As described above, in a case with the lanthanum (La) element, the SiN layer may not be maintained due to the relatively large reactivity of the La element, and an entirely different crystallized structure may be observed after the thermal process. The lanthanide (Ln) element may have relatively low energy for forming a rare earth (RE) oxyapatite structure as shown in FIG. 4. On the other hand, in a case where the lanthanide has a size smaller than Gd, the energy for forming the RE-oxyapatite structure may be relatively high, and thus, the reactivity with the SiN may be relatively low. In FIG. 4, a vertical axis denotes a formation enthalpy.

As described above, when a lanthanide has a relatively large size, e.g., La, the SiN charge trap layer may be difficult to maintain due to the relatively large reactivity with the silicon. For example, an undesired degradation of the memory characteristic may be caused, and an undesired crystallized structure may be shown.

Unlike the La element, a lanthanide (Ln) having a relatively small size, e.g., Gd, may have relatively low reactivity. Therefore, when the high dielectric constant insulating layer includes the Gd element or a smaller lanthanide (Ln), the reactivity with the SiN layer may be reduced, and thus, an interfacial reaction between the insulating layer and the SiN charge trap layer may be minimized or reduced. Therefore, the SiN layer may be maintained, and the relatively high dielectric constant and the relatively large energy band gap, which are advantages of the high dielectric constant insulating layer including the lanthanides (Ln), may be obtained.

Therefore, the charge trap memory device according to example embodiments may include the blocking insulating layer that is formed of a material including the Gd element or a smaller lanthanide (Ln). Therefore, a relatively high dielectric constant and relatively large energy band gap may be obtained, and even when the charge trap layer is formed of a material including silicon, the charge trap layer may be maintained. Therefore, the charge trap memory device having improved reliability due to the reduction of an operating voltage and enhanced memory characteristics may be realized. Hereinafter, the charge trap memory device according to example embodiments will be described in more detail with reference to accompanying drawings. In the drawings, the thicknesses of layers and regions are exaggerated for clarity.

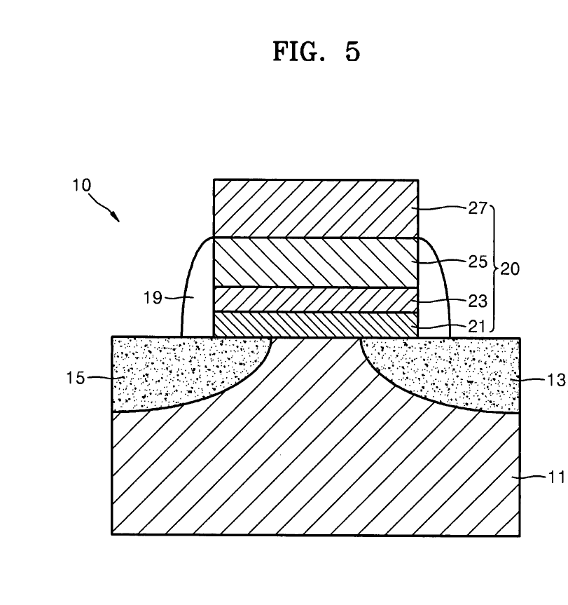

FIG. 5 schematically illustrates a charge trap memory device 10 according to example embodiments. Referring to FIG. 5, the charge trap memory device 10 may include a substrate 11, and a gate structure 20 formed on the substrate 11. The substrate 11 may include a first impurity region 13 and a second impurity region 15 in which predetermined conductive impurities are doped. One of the first and second impurity regions 13 and 15 may be used as a drain (D), and the other may be used as a source (S).

The gate structure 20 may include a tunnel insulating layer 21 formed on the substrate 11, a charge trap layer 23 formed on the tunnel insulating layer 21, and a blocking insulating layer 25 formed on the charge trap layer 23. A gate electrode 27 may be formed on the blocking insulating layer 25. In FIG. 5, reference numeral 19 denotes a spacer.

The tunnel insulating layer 21 may be a layer for tunneling electrical charges, and may be formed on the substrate 11 so as to contact the first and second impurity regions 13 and 15. The tunnel insulating layer 21 may be a tunneling oxide layer that is formed of SiO₂, various high-k oxide materials and/or an oxide material including a combination thereof.

Otherwise, the tunnel insulating layer 21 may be formed of a silicon nitride layer, for example, Si₃N₄. The silicon nitride layer may be formed to have a relatively low density of impurities (for example, the impurity density may be similar to that of the silicon oxide layer), and to have improved interfacial characteristics with the silicon. In order to form the silicon nitride layer of improved quality, the silicon nitride layer forming the tunnel insulating layer 21 may be formed using a jet vapor deposition method. When the silicon nitride layer is formed using the above method, a defectless silicon nitride layer (Si₃N₄) having the impurity density that is not higher than that of the silicon oxide layer and the improved interfacial characteristics with the silicon may be formed. Otherwise, the tunnel insulating layer 21 may be formed of a dual-layered structure including the silicon nitride layer and the oxide layer.

As described above, the tunnel insulating layer 21 may be formed to have a single layer structure including the oxide layer or the nitride layer, and/or a multi-layered structure including materials having energy band gaps that are different from each other. The charge trap layer 23 may be a region where the information is stored by the charge trapping. The charge trap layer 23 may be formed of a material including silicon, for example, SiN, or various materials and various structures. For example, the charge trap layer 23 may be formed to include one of a polysilicon, nitride material, high-k dielectric material having the relatively high dielectric constant and/or nanodots.

For example, the charge trap layer 23 may be formed of a nitride material, e.g., Si₃N₄ and/or a high-k oxide material, e.g., SiO₂, HfO₂, ZrO₂, Al₂O₃, HfSiON, HfON and/or HfAlO. In addition, the charge trap layer 23 may include a plurality of nanodots that are discontinuously disposed as charge trap sites. The nanodots may be formed as nano-crystals. The gate electrode 27 may be formed of a metal layer. For example, the gate electrode 27 may be formed of aluminum (Al). Metals, e.g., Ru and TaN, and/or a silicide material, e.g., NiSi, which are generally used as gate electrodes in semiconductor memory devices, may be used to form the gate electrode 27.

The blocking insulating layer 25 may block the charges that pass through the charge trap layer 23 and move upward, and may be formed of a material including one of the lanthanides (Ln), e.g., Gd and/or a smaller element among the lanthanides (Ln) so as to ensure the relatively high dielectric constant and the relatively large energy band gap simultaneously.

The lanthanides may include 14 elements from Cerium (Ce:58) to Lutetium (Lu:71), or 15 elements including lanthanum (La). Therefore, the lanthanides (Ln) having sizes equal to that of Gd or smaller are Gd, Tb, Dy, Ho, Er, Tm, Yb, and Lu. Hereinafter, Gd or smaller lanthanides (Ln) will be referred to as “small lanthanides (Ln)” for the convenience of explanation. The blocking insulating layer 25 may be formed of the material including Gd or smaller lanthanides (Ln), and Al as described above. The blocking insulating layer 25 may be the high dielectric constant insulating layer formed of a combination of small lanthanides (Ln)—Al—O, for example, a combination of Gd—Al—O. The blocking insulating layer 25 may be formed of, for example, GdAlO. In addition, the blocking insulating layer 25 may be formed of a material including Gd or a smaller lanthanide (Ln) element, Al, and nitrogen. For example, the blocking insulating layer 25 may be formed of GdAlON.

As described above, when the blocking insulating layer 25 is formed of the material including the small lanthanide (Ln) element, the blocking insulating layer that may ensure the relatively high dielectric constant and the relatively large energy band gap simultaneously may be obtained. In addition, even when the charge trap layer 23 is formed of the material including silicon, the charge trap layer 23 may be maintained.

According to the charge trap memory device of example embodiments, the blocking insulating layer may be formed of the material including Gd or a smaller lanthanide (Ln) so that the relatively high dielectric constant and the relatively large energy band gap are ensured simultaneously, and the interfacial reaction between the charge trap layer and the blocking insulating layer may be minimized or reduced even when the charge trap layer is formed of the material including the silicon.

Therefore, in the memory device, the reliability due to the reduced operating voltage may be improved with the improved memory operating characteristics. For example, the charge trap memory device having an increased program speed and improved erase characteristics may be realized. In addition, because the charge trap layer may be maintained even if the charge trap layer is formed of the material including silicon, the degradation of the memory characteristics may be prevented or reduced, and accordingly, the reliability of the memory device may be improved.

While example embodiments have been particularly shown and described with reference to example embodiments thereof, it will be understood by those of ordinary skill in the art that various changes in form and details may be made therein without departing from the spirit and scope of the following claims.

What is claimed is:

1. A charge trap memory device comprising:
a tunnel insulating layer on a substrate;
a charge trap layer on the tunnel insulating layer; and
a blocking insulating layer formed of a material including Gd or a smaller lanthanide element on the charge trap layer.

2. The charge trap memory device of claim 1, wherein the blocking insulating layer is formed of a material including Gd or a smaller lanthanide element, and aluminum (Al).

3. The charge trap memory device of claim 2, wherein the blocking insulating layer is formed of a material including a combination of Gd or a smaller lanthanide element having the formula (Ln)—Al—O.

4. The charge trap memory device of claim 2, wherein the blocking insulating layer is formed of a material including Gd or a smaller lanthanide element (Ln), aluminum, and nitrogen.

5. The charge trap memory device of claim 4, wherein the blocking insulating layer is formed of GdAlON.

6. The charge trap memory device of claim 1, wherein the charge trap layer is formed of a material including silicon.

7. The charge trap memory device of claim 6, wherein the charge trap layer includes a SiN material.

8. The charge trap memory device of claim 1, wherein the charge trap layer is formed of one selected from polysilicon, nitride material, nanodots, and high-k dielectric materials.

9. The charge trap memory device of claim 1, further comprising:
a gate electrode on the blocking insulating layer.

10. A method of manufacturing a charge trap memory device comprising:
forming a tunnel insulating layer on a substrate;
forming a charge trap layer on the tunnel insulating layer; and
forming a blocking insulating layer formed of a material including Gd or a smaller lanthanide element on the charge trap layer.

11. The method of claim 10, wherein the blocking insulating layer is formed of a material including Gd or a smaller lanthanide element, and aluminum (Al).

12. The method of claim 11, wherein the blocking insulating layer is formed of a material including a combination of Gd or a smaller lanthanide element having the formula (Ln)—Al—O.

13. The method of claim 11, wherein the blocking insulating layer is formed of a material including Gd or a smaller lanthanide element (Ln), aluminum, and nitrogen.

14. The method of claim 13, wherein the blocking insulating layer is formed of GdAlON.

15. The method of claim 10, wherein the charge trap layer is formed of a material including silicon.

16. The method of claim 15, wherein the charge trap layer includes a SiN material.

17. The method of claim 10, wherein the charge trap layer is formed of one selected from polysilicon, nitride material, nanodots, and high-k dielectric materials.

18. The method of claim 10, further comprising:
forming a gate electrode on the blocking insulating layer.
